(19) United States
(12) Patent Application Publication
(10) Pub. No.: US 2007/0042178 A1
(43) Pub. Date: Feb. 22, 2007

(54) Pulverized organic semiconductors and method for vapor phase deposition onto a support

(75) Inventors: Bernd Sachweh, Meckenheim (DE); Joachim Rosch, Ludwigshafen (DE); Markus Bold, Dirmstein (DE); Thomas Gessner, Heidelberg (DE)

Correspondence Address: OBLON, SPIVAK, MCCLELLAND, MAIER & NEUSTADT, P.C., 1940 DUKE STREET, ALEXANDRIA, VA, 22314, US

(73) Assignee: BASF Aktiengesellschaft, Ludwigshafen (DE)

(21) Appl. No.: 10/554,841

(22) PCT Filed: Apr. 16, 2004
(86) PCT No.: PCT/EP04/04039

§ 371 Date: Oct. 28, 2005

(30) Foreign Application Priority Data
Apr. 30, 2003 (DE) 103 19 742.7

(51) Int. Cl. C23C 16/00

(52) U.S. Cl. 428/336; 427/248.1

(57) ABSTRACT

The invention relates to a process for vapor deposition of one or more compounds onto a support, in which (i) the compound is introduced in a solid or gaseous state into a carrier gas stream, (ii) the compound is present in a gaseous state in the carrier gas stream, (iii) the gaseous compound is precipitated, (iv) the compound precipitated in step (iii) is once again brought into the gaseous state, and (v) the gaseous compound is subsequently precipitated on the support, wherein the carrier gas stream comprising the gaseous compound(s) is cooled to a temperature below the sublimation temperature of the compound(s) by introduction of a gas stream.

The present invention relates to a process for the vapor deposition of one or more compounds which are preferably solid at 25° C. and 1 bar onto a support, in which
(i) the compound is introduced in a solid or gaseous state, preferably a solid state, into a carrier gas stream,
(ii) the compound is present in a gaseous state in the carrier gas stream and/or, preferably, the compound is brought into the gaseous state in the carrier gas stream,
(iii) the gaseous compound(s) is/are precipitated,
(iv) the compound precipitated in step (iii) is once again brought into the gaseous state, preferably sublimed, and
(v) the gaseous compound is subsequently precipitated, preferably vapor deposited, preferably in the form of a preferably homogeneous layer, on the support which preferably has a temperature below the sublimation temperature of the compound.

The invention further provides supports obtainable in this way and, in particular, organic light-emitting diodes or photovoltaic cells comprising the supports of the present invention. In addition, the invention relates to pulverized organic semiconductor compounds.

Organic light-emitting diodes or organic solar cells based on a semiconducting-layer structure are generally known. Production of the very thin, usually amorphous layers of organic material on a support in a quality- and quantity-controlled manner is of particular importance to the function of these apparatuses.

In the vapor deposition process (OVPD: organic vapor phase deposition) described in the articles by M. Baldo et al., Advanced Materials, 1998, 10, No. 18, pages 1505 to 1514, and M. Stein et al., Journal of Applied Physics, 89, 2, pages 1470 to 1476, vaporizable crystalline or amorphous solids are precipitated on a substrate via the gas phase. The starting state of these solids is generally the solid in pulverized form. These powders are generally firstly vaporized from a source maintained at above the vaporization or sublimation temperature and mixed with a gas stream which is likewise kept at above the sublimation temperature. Powders are customarily produced by milling processes. The engineering outlay and energy consumption of these milling processes increases disproportionately with decreasing particle size, so that powders having particle diameters of less than one micron are virtually impossible to obtain. A disadvantage of this procedure is that the source has to be kept at above the sublimation temperature for the entire duration of the coating process. Very many substances, especially organic substances, begin to decompose at the sublimation temperature. As a result, the gas stream becomes contaminated with undesirable decomposition products. Furthermore, many powders begin to cake or sinter at the sublimation temperature, causing a decrease in the specific surface area, which in turn undesirably reduces the vaporization rate.

It is an object of the present invention to develop a process for the vapor deposition of one or more, preferably organic compounds onto one or more supports, in which the compound(s) is/are introduced in a solid or gaseous state, preferably a solid state, into a carrier gas stream, the compound(s) is/are preferably brought into the gaseous state, i.e. sublimed or left in the gaseous state, in the carrier gas stream, the gaseous compound(s) is/are subsequently precipitated, the precipitated compound(s) is/are then once again brought into the gaseous state and the gaseous compound is subsequently deposited on the support, preferably in the form of a preferably homogeneous layer. In the process to be developed, the abovementioned disadvantages should be avoided. In particular, decomposition of sensitive materials and fluctuating vaporization rates should be significantly reduced. In addition, pulverized compounds, in particular pulverized organic semiconductors, which are particularly suitable for vapor deposition onto supports and thus for the production of organic light-emitting diodes or photo-voltaic cells should be able to be obtained.

We have found that this object is achieved by cooling the carrier gas stream comprising the gaseous compound(s) to a temperature below the sublimation temperature of the compound(s) by introduction of a gas stream, i.e. a further gas stream, i.e. a quench gas stream, so that the compound(s) is/are preferably desublimed and thus converted into the solid state. The appropriate sublimation temperatures for a given substance at a chosen pressure can either be taken from the specialist literature or determined by means of simple experiments for example by varying the temperature of the quench gas and checking for desublimation of the compound.

According to the present invention, a very finely divided powder which has a very narrow particle size distribution and has an increased vaporization rate at a given temperature and vaporizes in a narrow temperature window can be obtained by precipitation of the gaseous compounds by introduction of the quench gas. A further advantage is the reduced tendency for the compounds to decompose. In the case of components which are difficult to sublime, the temperature of the vaporization process can be lowered, so that any further components present are not unnecessarily thermally stressed. In addition, the reduction of the particle size significantly increases the vapor deposition rate so that acceleration of a vaporization process can be achieved. This advantage applies particularly to molecular jet processes in which a preheated gas stream is passed at low pressure through the powder to be vaporized. The narrow particle size distribution (geometric standard deviation<1.5) results in uniform loading of the carrier gas stream with the component to be vapor deposited, so that ideal uniform layer thicknesses on the support can be produced. Compared to milled powders, the vaporization temperature measured by thermogravimetric analysis is on average reduced by 30 K. After use in a vapor deposition unit, the proportion of decomposed material, detectable as residue in the vaporization source, decreases on average from 30% to 4%. As a result of the narrow particle size distribution, the vaporization rate remains constant within a narrow range over the entire vaporization time. This can be seen from the unimodal peak in the derivative with respect to time of the TGA curve. A further possible method of confirmation is an isothermal TGA just below the sublimation temperature.

The present invention thus provides a process for vapor deposition of one or more compounds onto a support by bringing a compound into the gaseous state and subsequently precipitating it on a support, with the compound in the form of a powder having a mean particle size of less than 10 μm being brought into the gaseous state by sublimation.

According to the present invention, use is thus made of at least two gas streams of which one gas stream is the carrier gas stream comprising the gaseous compounds and the other gas stream, also referred to as quench gas stream in the present text, serves to cool the carrier gas stream to a temperature below the sublimation temperature of the compound. The gas stream which is introduced into the carrier gas stream, i.e. the quench gas stream, preferably has a temperature which is at least 10° C., preferably from 100 to 700° C., below the temperature of the carrier gas stream. The volume ratio of carrier gas stream to gas stream introduced is preferably from 10:1 to 1:100. The volume flows can usually be chosen in a known manner by persons skilled in the art as a function of the size of the plant.

The quench gas stream is preferably introduced through the porous wall of a tube. The carrier gas stream can flow around this porous tube so that addition of the cold quench gas occurs from the interior of the tube through the pores into the carrier gas stream. It is likewise possible for the tube through which the carrier gas stream flows itself to have a porous wall so that addition of the cold quench gas occurs from the outside of the tube into the hot carrier gas stream. The two methods of addition can also be combined. The quench gas is preferably added by means of axial addition to the carrier gas stream. Examples of materials which are suitable for producing such tubes are porous sintered metal and sintered ceramic tubes.

The solid compounds can be brought into the carrier gas stream by introducing the compounds in a solid state into the carrier gas stream and/or vaporizing the compound and introducing it in a gaseous state into the carrier gas stream. The sensitive organic compounds are preferably introduced in solid form to the carrier gas stream. This means that the compound is introduced into the carrier gas stream at below the sublimation temperature and undesirably long thermal stressing of the compound is thus significantly reduced. Vaporization or sublimation of the compound to introduce it into the carrier gas stream can be dispensed with. For the purposes of the present text, the expression “compound” refers to the compound(s) which is/are to be precipitated on the support. The compound or compounds are preferably nonmetallic materials having melting points above 50° C. The compounds are particularly preferably organic semiconductor materials, with “organic” having the usual chemical meaning.

Step (i), i.e. the introduction of the compound into the carrier gas stream, can, according to the present invention, be carried out by generally known methods of introducing solid materials into a carrier gas stream, preferably by means of brush metering. Such a brush metering procedure is generally known. Appropriate apparatuses for brush metering are commercially available, for example from Palas®, Karlsruhe, Germany, under the name Partikeldosierer RBG 1000. The principle of brush metering is based on a stainless steel block (dispersing head) in which a brush is mounted so that it can rotate. From a preferably cylindrical reservoir, the compound to be introduced into the carrier gas stream is pushed against the rotating brush, so that individual particles of the compound are carried away by the brush. In a further part of the dispersing head, the compound present on and/or in the rotating brush is blown out of and/or off from the brush by means of a carrier gas stream and is transported away in the carrier gas stream through the dust exit nozzle. Further information on the Partikeldosierer RBG 1000 may be found in the operating instructions RBG-1000, Palase GmbH, 1994. The compounds are generally transferred in the solid state and as pulverized solids, preferably solids having a particle size with a mean diameter of from 1 nm to 100000 nm, particularly preferably from 5 nm to 10000 nm, preferably by the brush into the carrier gas stream. The compound is preferably introduced in a solid state into the carrier gas stream at below the sublimation temperature. The carrier gas stream is preferably a laminar gas stream which preferably has a carrier gas velocity in the range from 0.01 m/s to 1 m/s. The compound is preferably introduced in a solid state in a turbulence-free manner into the center of a laminar gas stream of the carrier gas. In this way, contact with the hot interior tube walls of the oven in which the compounds are sublimed and/or vaporized in step (ii) is reduced. This can be assisted by introducing a sheathing gas stream heated to the oven temperature coaxially around the carrier gas stream in order to reduce movement of particles to the interior tube wall. As carrier gas, it is possible to use generally known gases, preferably ones which are inert toward the compound to be taken up, for example air, carbon dioxide, noble gases, nitrogen. Preference is given to nitrogen, noble gases, for example argon, helium, neon, and/or carbon dioxide, in particular nitrogen, argon and/or carbon dioxide, or mixtures thereof. Steps (i), (ii) and (iii) are preferably carried out at a pressure, preferably of the carrier gas, of from 0.001 mbar to 110000 mbar, particularly preferably from 0.1 mbar to 1100 mbar. The respective sublimation temperature can be derived by a person skilled in the art directly from the chosen pressure. The carrier gas into which the compound is introduced, preferably in a solid state, preferably has a temperature of from 10° C. to 300° C., particularly preferably from 10° C. to 100° C. Preference is thus given to introducing the compound in a solid state into the carrier gas stream at below the sublimation temperature preferably by means of brush metering in (i).

Step (ii), i.e. maintenance of the compound in the gaseous state in the carrier gas when the compound is introduced in the gaseous state into the carrier gas and/or preferably vaporization or sublimation of the solid compound in the carrier gas stream, can be carried out by means of generally known heating apparatuses, for example by heating the carrier gas stream and the compound present in this gas stream to a temperature above the sublimation temperature by means of microwaves, infrared radiation sources and/or near infrared radiation sources. Heating of the carrier gas stream and the compound is preferably carried out in a hot wall oven. For the purposes of the present invention, the expression “hot wall oven” refers to an insulated flow tube which is preferably heated from the outside and preferably has a circular cross section. In this step (ii), the pulverized compound is preferably brought into the gas phase. Vaporization of the pulverized compound in the carrier gas stream can occur very quickly, so that the time between heating and precipitation can be minimized. The compound is preferably brought into the gaseous state in the carrier gas stream at from 100° C. to 1000° C., particularly preferably from 101° C. to 600° C. Preference is given to carrying out (ii) the conversion of the solid compound into the gaseous state at a pressure of from 0.1 to 2200 mbar.

The precipitation according to the present invention of the gaseous compound by introduction of quench gas occurs as a result of cooling and thus desublimation. According to the present invention, cooling of the gaseous compounds in the carrier gas stream to a temperature below the sublimation temperature thus occurs by the carrier gas stream comprising the gaseous compound being cooled by introduction of a second gas stream, i.e. a quench gas stream. The temperature can be set to a desired value via the volume ratio of carrier gas stream to quench gas stream. The quench gas can be, for example, one of the gases which can also be used as carrier gas. Precipitation or deposition of the gaseous compound in step (iii) is preferably carried out at a pressure of from 0.1 mbar to 2200 mbar. Precipitation of the gaseous compound from the carrier gas stream is preferably carried out at a temperature of the carrier gas, i.e. after introduction of the quench gas, of from 10° C. to 300° C., particularly preferably from 10° C. to 150° C., in particular from 10 to 100° C.

The compound is preferably in the gaseous state between vaporization and/or sublimation in the heating phase (ii) and precipitation (iii) for a period of not more than 100 s, particularly preferably from 0.01 s to 30 s, in particular from 1 s to 10 s, i.e. the time for which the compound is kept at a temperature above the sublimation temperature is preferably very short, thus avoiding decomposition of the sensitive compounds.

The pulverized compounds which can be obtained in this step (iii) are preferably precipitated on surfaces of generally known electrostatic precipitators or of particle filters, with the pulverized compounds being removed from the surface from time to time and being stored in powder containers. Storage can be carried out under the pressures described under (iii), preferably at ambient pressure.

The compound(s) precipitated in step (iii) is/are preferably in the form of powder having a mean particle size of preferably less than 10 μm, particularly preferably from 1 nm to 1000 nm, in particular from 1 nm to 200 nm. The mean particle size is defined as the arithmetic mean over all particle sizes of the particle size distribution.

Here, the distribution width of the particle size measured as geometric standard deviation of the compound(s) precipitated in the form of powder in step (iii) is preferably less than 2, particularly preferably less than 1.5.

The compound(s) precipitated in the form of powder in step (iii) preferably has/have a specific surface area measured by the BET method of greater than 0.1 m²/g, particularly preferably greater than 5 m²/g, in particular greater than 10 m²/g.

As indicated above, the gaseous compound(s) can be cooled to a temperature below the sublimation temperature of the compound(s) and thereby precipitated in step (iii) by introduction of a colder gas stream into the carrier gas stream comprising the gaseous compound(s).

The solid compounds precipitated in step (iii) can preferably be given an electric charge, for example by charging the particles electrically by means of a corona discharge. Accordingly, the compound(s) precipitated in step (iii) preferably has/have a surface charge of from one (1) to ten (10) elementary charges, as can be confirmed, for example, by means of a Faraday cup arrangement.

The compounds precipitated in step (iii) are preferably brought back into the gaseous state in step (iv), for example as described in (i) and (ii), i.e. introduced in solid and/or gaseous form into a carrier gas stream and brought into the gaseous state in the carrier gas stream, and subsequently precipitated on a support in step (v). The actual vapor deposition of the compound which has been brought into the gaseous state in step (iv) onto the support in step (v) is preferably carried out by depositing the gaseous compound onto the support in step (v) at a temperature of the support which is less than the sublimation temperature of the compound. As indicated above, the sublimation temperature of the respective compound at a particular pressure may be found in the specialist literature or can be easily determined by varying the temperature of the support. The vapor deposition of the gaseous compound onto the support in step (v) is preferably carried out at a temperature of the support of from 10° C. to 100° C. Due to the low temperature of the support, the gaseous compound is desublimed and forms a preferably homogeneous layer of the compound on the support. While a very finely divided powder which is very suitable for rapid vaporization or sublimation under mild conditions is produced in step (iii) by cooling with the quench gas, a very homogeneous layer is produced on the desired support in step (v).

Possible supports onto which the compounds can be precipitated in steps (v) and, if appropriate, (iii) are sheet-like substrates made of plastic, glass, ceramic, semiconductors or metal. The support or supports is/are preferably glass, glass coated with indiumtin oxide (ITO-glass) and glass coated with semiconductor materials such as silicon, e.g. active-matrix substrates comprising thin layer transistors made of silicon semiconductors on glass.

The supports with the vapor-deposited compound or compounds which are obtainable according to the present invention and preferably have a layer having a total thickness of from 1 nm to 500 nm, particularly preferably from 10 to 400 nm, are particularly useful for producing electronic devices, for example organic light-emitting diodes, thin film solar cells or other apparatuses having an electroluminescent layer structure, e.g. photovoltaic cells, preferably organic light-emitting diodes and photovoltaic cells, particularly preferably light-emitting diodes.

It has been found, particularly advantageously, that the process of the present invention makes it possible to obtain organic semiconductor compounds pulverized in step (iii) which have a mean particle size of less than 10 μm, particularly preferably from 1 nm to 1000 nm, in particular from 1 nm to 200 nm, with the distribution width measured as geometric standard deviation of the particle size particularly preferably being less than 2, more preferably less than 1.5, and the specific surface area preferably being greater than 0.1 m²/g, particularly preferably greater than 5 m²/g, in particular greater than 10 m²/g. In a particularly preferred embodiment, the pulverized organic semiconductor compounds of the present invention bear from 1 to 10 elementary charges which can be measured, for example, using a Faraday cup arrangement. The pulverized organic semiconductor compounds of the present invention can be in the form of pellets or tablets.

### EXAMPLES

1. Preparation of Nanoparticulate Copper Phthalocyanine Having a Narrow Particle Size Distribution

Copper phthalocyanine powder was introduced into a stream of nitrogen (about 1 m³/h) at ambient conditions by means of a brush metering apparatus (from Palas, RBG 1000). The stream was subsequently fed into a hot wall oven, viz. an externally heated, insulated flow tube having a circular cross section. In this, the solid copper phthalocyanine was brought completely into the gas phase at mean temperatures of from 500 to 600° C. Appropriate flow conditions were employed to avoid contact of the solid copper phthalocyanine with the hot interior tube walls of the furnace and thus thermal decomposition of the particles. Desublimation was subsequently carried out in a quenching apparatus by axial introduction of cold nitrogen in an amount of from 0.5 to 2.0 m³/h into the hot gas stream laden with copper phthalocyanine vapor. This resulted in the gas stream being cooled to below 250° C. Variation of the amount of cold gas enables both the size of the particles and the distribution width to be controlled. After desublimation, the fine particles were separated off in an electrofilter.

2. Confirmation of the Reduced Vaporization Temperature and the Increased Vaporization Rate

In a thermogravimetric experiment, a sample of raw copper phthalocyanine pigment (milled, particle size>1 μm) and a sample of the copper phthalocyanine nanopowder prepared in example 1 were heated at a heating rate of 5 K/min and the loss in weight of the crucible was recorded as a function of time. The vaporization temperature was determined as the intersection of the tangents at the points of inflection of the weight/time curve with the baseline. In the case of the raw pigment, this is 422.7° C. In the case of the nanopowder of the present invention, it is 400.7° C.

The vaporization rate was determined as the maximum of the first derivative with respect to time of the weight decrease. The vaporization rate of the raw pigment is 9.3%/min, while the vaporization rate of the nanopowder of the present invention is 21.9%/min. The TGA curve of the raw pigment also has a shoulder at higher temperatures which is attributable to the broad particle size distribution of the milled raw pigment. On the other hand, the vaporization curve of the nanopowder having a narrow particle size distribution is monomodal.

We claim:

1. A process for vapor deposition of one or more compounds onto a support, in which
(i) the compound is introduced in a solid or gaseous stage into a carrier gas stream,
(ii) the compound is present in a gaseous state in the carrier gas stream,
(iii) the gaseous compound is precipitated,
(iv) the compound precipitated in step (iii) is once again brought into the gaseous state, and
(v) the gaseous compound is subsequently precipitated on the support,
wherein the carrier gas stream comprising the gaseous compound(s) is cooled to a temperature below the sublimation temperature of the compound(s) by introduction of a gas stream.

2. A process as claimed in claim 1, wherein the gas stream which is introduced into the carrier gas stream in step (iii) has a temperature which is at least 10° C. below the temperature of the carrier gas stream.

3. A process as claimed in claim 1 or 2, wherein the volume ratio of carrier gas stream to gas stream introduced is from 10:1 to 1:100.

4. A process as claimed in any of claims 1 to 3, wherein, in (i), the compound is introduced in a solid state into the carrier gas stream at below the sublimation temperature by means of brush metering.

5. A process as claimed in any of claims 1 to 4, wherein the carrier gas into which the compound is introduced in a solid state in step (i) has a temperature of from 10° C. to 100° C.

6. A process as claimed in any of claims 1 to 5, wherein the compound is brought into the gaseous state in the carrier gas stream at from 100° C. to 1000° C.

7. A process as claimed in any of claims 1 to 6, wherein the compound(s) precipitated in step (iii) is/are in the form of powder having a mean particle size of less than 10 μm.

8. A process as claimed in any of claims 1 to 7, wherein the distribution width measured as geometric standard deviation of the particle size of the compound(s) precipitated in the form of powder in step (iii) is less than 2.

9. A process as claimed in any of claims 1 to 8, wherein the compound(s) precipitated in the form of powder in step (iii) has/have a specific surface area of greater than 0.1 m²/g.

10. A process as claimed in any of claims 1 to 9, wherein the solid compounds precipitated in step (iii) are given an electric charge.

11. A process as claimed in any of claims 1 to 10, wherein the compound(s) precipitated in step (iii) bear(s) from one to ten elementary charges.

12. A process as claimed in any of claims 1 to 11, wherein the compound(s) used are organic semiconductor materials.

13. A process as claimed in any of claims 1 to 12, wherein the solid compound is brought into the gaseous state at a pressure of from 0.1 to 2200 mbar.

14. A process as claimed in any of claims 1 to 13, wherein the deposition of the gaseous compound on the support in step (v) is carried out at a pressure of from 0.1 mbar to 100 mbar.

15. A process as claimed in any of claims 1 to 14, wherein the vapor deposition of the gaseous compound onto the support in step (v) is carried out at a temperature of the support which is less than the sublimation temperature of the compound.

16. A process as claimed in any of claims 1 to 15, wherein the (v) vapor deposition of the gaseous compound onto the support is carried out at a temperature of the support of from 10° C. to 100° C.

17. A process for the vapor deposition of one or more compounds onto a support, in which a compound is brought into the gaseous state and is subsequently precipitated on a support, wherein the compound in the form of a powder having a mean particle size of less than 10 μm is brought into the gaseous state by sublimation.

18. A pulverized organic semiconductor compound having a mean particle size of less than 10 μm obtainable by a process as claimed in any of claims 1 to 13.

19. A pulverized organic semiconductor compound having a mean particle size of less than 10 μm.

20. A pulverized organic semiconductor compound as claimed in claim 19 having a distribution width measured as geometric standard deviation of the particle size of less than 2 and a specific surface area of greater than 0.1 m²/g.

21. A pulverized organic semiconductor compound as claimed in claim 19 or 20, wherein the particles of the powder bear from 1 to 10 elementary charges.

22. A pulverized organic semiconductor compound as claimed in any of claims 19 to 20 in the form of pellets or tablets.

23. A support onto which a compound or compounds has/have been vapor deposited obtainable by a process as claimed in any of claims 1 to 17.

24. A support onto which a compound or compounds has/have been vapor deposited as claimed in claim 23, wherein the vapor-deposited layers have a total thickness of from 1 nm to 500 nm.

25. An organic light-emitting diode comprising a support as claimed in claim 23 or 24.

26. A photovoltaic cell comprising a support as claimed in claim 23 or 24.
